(19) United States
(12) Patent Application Publication
(10) Pub. No.: US 2012/0269967 A1
(43) Pub. Date: Oct. 25, 2012

(54) Hot Wire Atomic Layer Deposition Apparatus And Methods Of Use

(75) Inventors: Joseph Yudovsky, Campbell, CA (US); Garry K. Kwong, San Jose, CA (US); Dieter Haas, San Jose, CA (US); Steven D. Marcus, San Jose, CA (US); Timothy W. Weidman, Sunnyvale, CA (US)

(73) Assignee: Applied Materials, Inc., Santa Clara, CA (US)

(21) Appl. No.: 13/437,567

(22) Filed: Apr. 2, 2012

Related U.S. Application Data
(60) Provisional application No. 61/478,102, filed on Apr. 22, 2011.

(51) Int. Cl. C23C 16/455; B05B 1/14

(52) U.S. Cl. 427/255.26; 118/724; 239/548

(57) ABSTRACT

Provided are gas distribution plates for atomic layer deposition apparatus including a hot wire or hot wire unit which can be heated to excite gaseous species while processing a substrate. Methods of processing substrates using a hot wire to excite gaseous precursor species are also described.

### CROSS-REFERENCE TO RELATED APPLICATIONS

This application claims the benefit under 35 U.S.C. 119(e) to U.S. Provisional Application No. 61/478,102, filed Apr. 22, 2011.

### BACKGROUND

Embodiments of the invention generally relate to an apparatus and a method for depositing materials. More specifically, embodiments of the invention are directed to a atomic layer deposition chambers with a hot wire for exciting gaseous species before contacting the substrate surface.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

There is an ongoing need in the art for apparatuses and methods of rapidly and efficiently processing substrates by atomic layer deposition.

### SUMMARY

Embodiments of the invention are directed to gas distribution plates comprising an input face, an output face and a wire. The input face comprises a first precursor gas input configured to receive a flow of a first precursor gas and a second precursor gas input configured to receive a flow of a second precursor gas. The output face has a plurality of elongate gas ports configured to direct flows of gases toward a substrate adjacent the output face. The elongate gas ports include at least one first precursor gas port and at least one second precursor gas port. The at least one first precursor gas port is in flow communication with the first precursor gas and the at least one second precursor gas port in flow communication with the second precursor gas. The wire is positioned within at least one of the first precursor gas port and the second precursor gas port and is connected to a power source to heat the wire. In detailed embodiments, the wire comprises tungsten. In detailed embodiments, the wire can be heated to excite species in a gas flowing across the wire.

In some embodiments, the gas distribution plate further comprises a tensioner connected to the wire to provide a tension. In detailed embodiments, the tensioner comprises a spring. In specific embodiments, the tension is sufficient to prevent significant sagging in the wire and breakage of the wire. According to some embodiments, the tensioner is attached to the input face of the gas distribution plate.

According to some embodiments, the wire is within an enclosure attached to the output face and positioned so that gases exiting one or more of the first precursor gas port and the second precursor gas port pas through the enclosure.

In some embodiments, the plurality of elongate gas ports consist essentially of, in order, a leading first precursor gas port, a second precursor gas port and a trailing first precursor gas port. In detailed embodiments, the wire is a single wire extending along both first precursor gas ports and wrapping around the second precursor gas port. In specific embodiments, there are two wires, a first wire extending along the leading first precursor gas port and a second wire extending along the trailing first precursor gas port. In one or more embodiments, the wire extends along the at least one second precursor gas port.

In some embodiments, the plurality of elongate gas ports consist essentially of, in order, at least two repeating units of alternating first precursor gas ports and second precursor gas ports followed by a trailing first precursor gas port. In detailed embodiments, the wire extends along each of the first precursor gas ports. In specific embodiments, the wire extends along each of the second precursor gas ports.

Additional embodiments of the invention are directed to processing chambers with the gas distribution plate described.

Further embodiments of the invention are directed to methods of processing a substrate. A substrate having a surface is laterally moved beneath a gas distribution plate comprising a plurality of elongate gas ports including at least one first precursor gas port configured to deliver a first precursor gas and at least one second precursor gas port configured to deliver a second precursor gas. The first precursor is delivered to the substrate surface. The second precursor gas is delivered to the substrate surface. Power is applied to a wire positioned within one or more of the at least one first precursor gas port and the at least one second precursor gas port to excite gaseous species in one or more of the first precursor gas and the second precursor gas, the excited species reacting with the surface of the substrate. Detailed embodiments further comprise applying a tension to the wire, the tension sufficient to prevent significant sagging of the wire and breakage of the wire.

Some embodiments of the invention are directed to methods of processing a substrate. A substrate is moved laterally adjacent a gas distribution plate having a plurality of elongate gas ports. The plurality of elongate gas ports consist essentially of, in order, a leading first precursor gas port, a second precursor gas port and a trailing first precursor gas port. A surface of the substrate is sequentially contacted with, in order, a first precursor gas stream from the leading first precursor gas port, a second precursor gas stream from the second precursor gas port and a first precursor gas stream from the trailing first precursor gas port. A gaseous species in one or more of the first precursor gas and the second precursor gas is excited before contacting the surface of the substrate by powering a wire positioned within either both the leading and trailing first precursor gas port or the second precursor gas port. In detailed embodiments, the method further comprises adjusting the tension of the wire to prevent substantial sagging and breakage of the wire.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional side view of an atomic layer deposition chamber according to one or more embodiments of the invention;

FIG. 2 shows a perspective view of a susceptor in accordance with one or more embodiments of the invention;

FIG. 3 shows a perspective view of a gas distribution plate in accordance with one or more embodiments of the invention;

FIG. 4 shows a front view of a gas distribution plate in accordance with one or more embodiments of the invention;

FIG. 5 shows a front view of a gas distribution plate in accordance with one or more embodiments of the invention;

FIG. 6 shows a front view of a gas distribution plate in accordance with one or more embodiments of the invention;

FIG. 7 shows a front view of a gas distribution plate in accordance with one or more embodiments of the invention;

FIG. 8 shows a front view of a gas distribution plate in accordance with one or more embodiments of the invention;

FIG. 9 shows a front view of a gas distribution plate in accordance with one or more embodiments of the invention;

FIG. 10 shows a perspective view of a wire enclosure for use with gas distribution plates in accordance with one or more embodiments of the invention;

FIG. 11 shows an isometric cross-section of a tensioner in accordance with one or more embodiments of the invention;

FIG. 12 shows a cross-sectional view of a gas distribution plate in accordance with one or more embodiments of the invention;

FIG. 13 shows a cross-sectional view of a gas distribution plate in accordance with one or more embodiments of the invention; and

FIG. 14 Shows a front view of a channel of a gas distribution plate in accordance with one or more embodiments of the invention.

### DETAILED DESCRIPTION

Embodiments of the invention are directed to atomic layer deposition apparatus and methods which provide excited gaseous species for reaction with the substrate surface. As used in this specification and the appended claims, the term “exited gaseous species” means any gaseous species not in the ground electronic state. For example, molecular oxygen may be excited to form oxygen radicals. The oxygen radicals being the excited species. Additionally, the terms “excited species”, “radical species” and the like are intended to mean a species not in the ground state. As used in this specification and the appended claims, the term “substrate surface” means the bare surface of the substrate or a layer (e.g., an oxide layer) on the bare substrate surface.

Embodiments of the invention relate to the implementation of hot wire technology to spatial atomic layer deposition. In traditional applications, either globally elevated temperature or plasma (e.g., DC, RF, microwave) technologies were used. According to one or more embodiments, the implementation of hot wire technology creates a localized high temperature during an ALD process. With this hot wire technology in spatial ALD processes, one or more of the temperature, power and quantity of other gases required for the process can be reduced. This reduces the cost of processing substrates and is more reliable to manufacture the process chamber and achieve higher throughput and film quality.

Generally, embodiments of the invention place a compatible material single wire or wires at a certain distance above the substrate. A certain tension is applied to the single wire or wires. Current flowing through the wire creates a localized high temperature which excites the reactant. When the radicalized species meet the precursor, they deposit a quality film on the substrate. The hot wire can be a single device such as a tubular device inserted from the front or a flange mount device mounted from the bottom. It contains all the necessary components to hold and tension the wire or wires, provide current to the wire or wires, component or material to compensate for the elongation of the wire and container, then place this single device at the path of reactant above the substrate. The wire can be integrally formed with the gas shower head together to simplify the power requirements. The wire can be formed in either a U shape, S shape or circular shape in the reactant path with one positive and one negative current lead for the whole shower head.

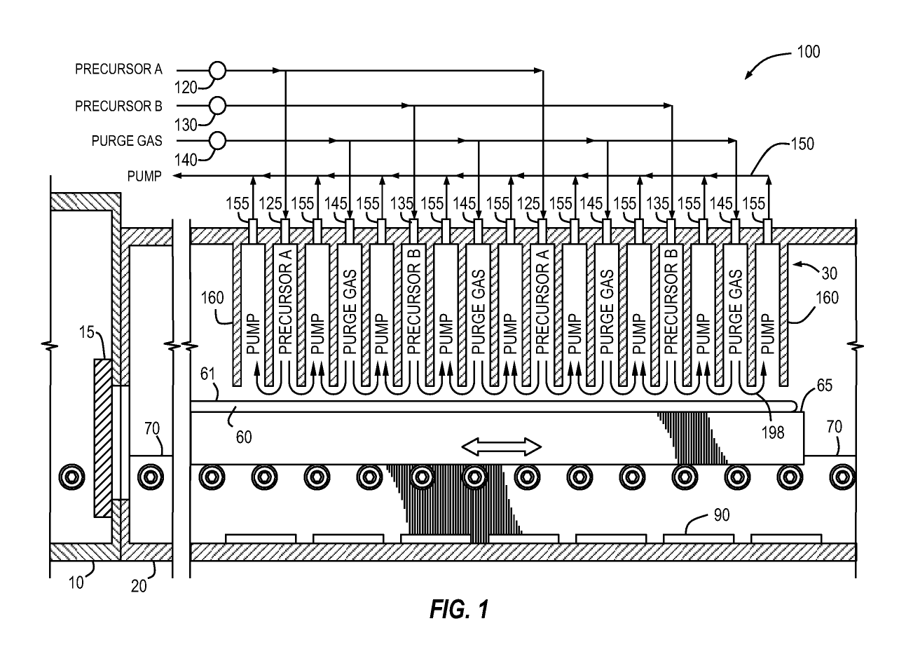

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A, a first precursor, into the processing chamber 20 through a plurality of gas ports 125. The precursor injector 130 is configured to inject a continuous (or pulse) stream of a reactive precursor of compound B, a second precursor, into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors. As used in this specification and the appended claims, the terms “reactive gas”, “reactive precursor”, “first precursor”, “second precursor” and the like, refer to gases and gaseous species capable of reacting with a substrate surface.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc. The frequency of power used to generate the plasma can be any known and suitable frequency. For example, the plasma frequency can be 2 MHz, 13,56 MHz, 40 MHz or 60 MHz, but other frequencies may be beneficial as well.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60. For example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads may be employed.

In operation, a substrate 60 is delivered (e.g., by a robot) to the load lock chamber 10 and is placed on a shuttle 65. After the isolation valve 15 is opened, the shuttle 65 is moved along the track 70. Once the substrate 60 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A emitted from gas ports 125 and the precursor of compound B emitted from gas ports 135, with the purge gas emitted from gas ports 145 in between. Injection of the purge gas is designed to remove unreacted material from the previous precursor prior to exposing the substrate surface 61 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface and around the lower portions of the partitions 160, and finally upward toward the vacuum ports 155. In this manner, each gas may be uniformly distributed across the substrate surface 61. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

The extent to which the substrate surface 61 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 61. The width between each partition, the number of gas ports disposed on the processing chamber 20, and the number of times the substrate is passed back and forth may also determine the extent to which the substrate surface 61 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 61 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward. In one or more embodiments, at least one radiant heat source 90 is positioned to heat the second side of the substrate.

The gas distribution plate 30 can be of any suitable length, depending on the number of layers being deposited onto the substrate surface 61. Some embodiments of the gas distribution plate are intended to be used in a high throughput operation in which the substrate moves in one direction from a first end of the gas distribution plate to the second end of the gas distribution plate. During this single pass, a complete film is formed on the substrate surface based on the number of gas injectors in the gas distribution plate. In some embodiments, the gas distribution plate has more injectors than are needed to form a complete film. The individual injectors may be controlled so that some are inactive or only exhaust purge gases. For example, if the gas distribution plate has one hundred injectors for each of precursor A and precursor B, but only 50 are needed, then 50 injectors can be disabled. These disabled injectors can be grouped or dispersed throughout the gas distribution plate.

Additionally, although the drawings show a first precursor gas A and a second precursor gas B, it should be understood that the embodiments of the invention are not limited to gas distribution plates with only two different precursors. There can be, for examples, a third precursor C and fourth precursor D dispersed throughout the gas distribution plate. This would enable one to create films with mixed or stacked layers.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat source 90, a heating plate, resistive coils, or other heating devices, disposed underneath the susceptor 66.

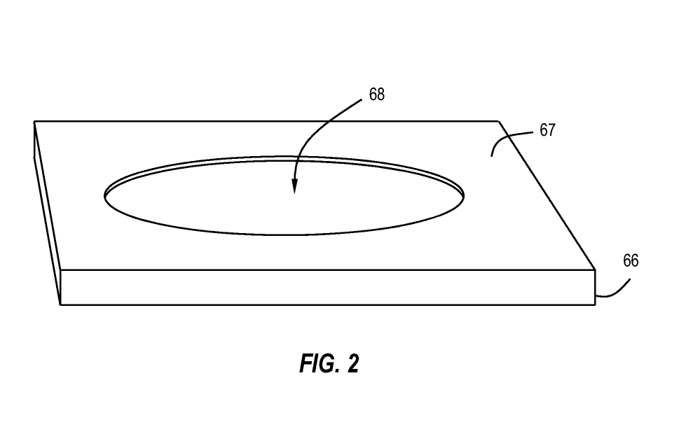

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

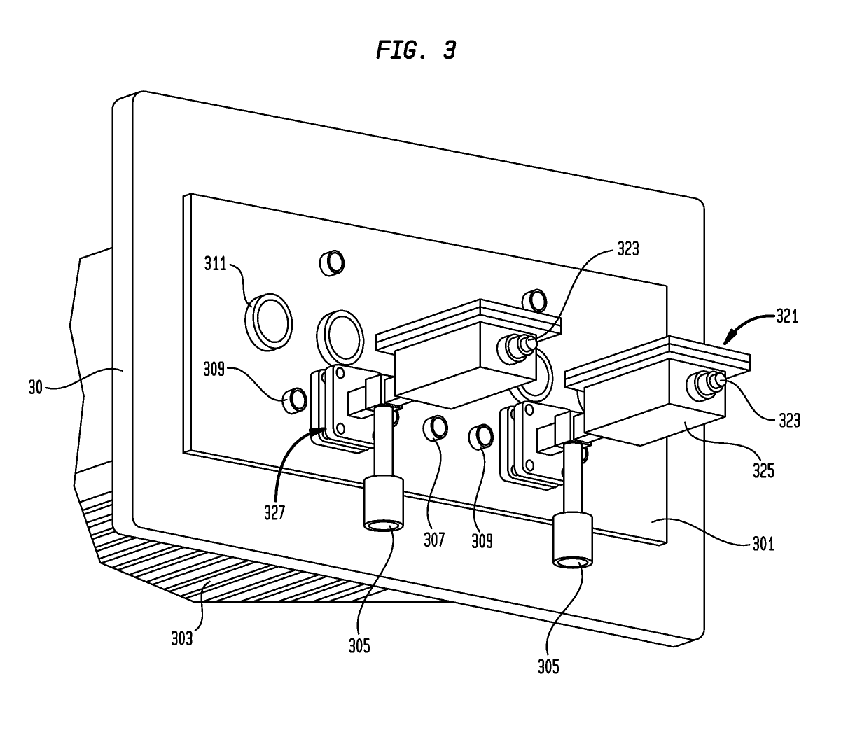

FIGS. 3-9 show gas distribution plates 30 in accordance with various embodiments of the invention. The gas distribution plates 30 comprise an input face 301 and an output face 303. The input face 301 (shown in FIG. 3) has a first precursor gas input 305 for receiving a flow of a first precursor gas A and a second precursor gas input 307 for receiving a flow of a second precursor gas B. The input face 301 also has inputs 309 for one or more purge gases and ports 311 for connecting to one or more vacuum ports. Although the configuration shown in FIG. 3 has two first precursor gas inputs 305, one second precursor gas input 307 and two purge gas inputs 309 visible, it will be understood by those skilled in the art that there can be more or less of each of these components, individually or in combination.

The specific embodiments illustrated in FIGS. 3-9 can be used with a reciprocal deposition system in which the substrate moves back and forth adjacent the gas distribution plate to deposit multiple layers. However, it should be understood that this is merely one embodiment and that the invention is not limited to reciprocal deposition techniques. Those skilled in the art will understand that a single large gas deposition plate with multiple sets of precursor injectors can be employed.

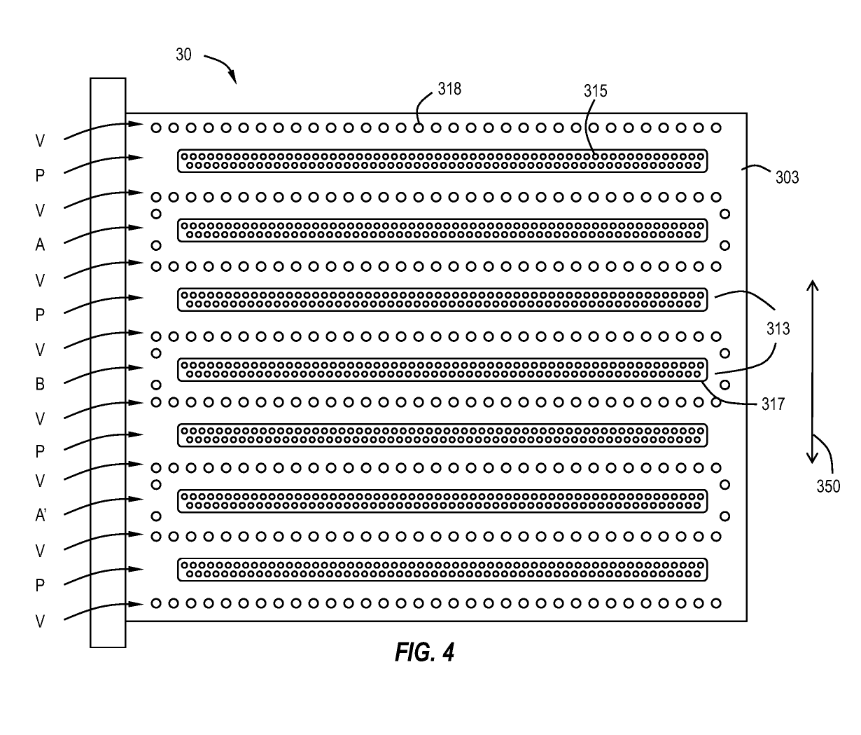

The output face 303, shown in FIGS. 4-7, has a plurality of elongate gas ports 313. The gas ports 313 are configured to direct flows of gases toward a substrate which may be positioned adjacent the output face 303. The elongate gas ports 313 include at least one first precursor gas port and at least one second precursor gas port. Each first precursor gas port is in flow communication with the first precursor gas input 305 to allow the first precursor to flow through the gas distribution plate 30. Each second precursor gas port is in flow communication with the second precursor gas input 307 to allow the second precursor to flow through the gas distribution plate 30.

As shown in FIG. 4, the gas ports may include a plurality of openings 315 within a channel 317. The channel 317 is a recessed slot within the output face of the gas distribution plate. The gases flow out of the openings 315 and are directed by the channel 317 walls toward the substrate surface. The openings 315 are shown as being circular, but it should be understood that the openings 315 can be any suitable shape including, but not limited to, square, rectangular and triangular. The number and size of the openings 315 can also be changed to fit more or less openings within each channel 317. In the detailed embodiment shown in FIG. 4, the purge gases (P), first precursor gas ports (A) and second precursor gas ports (B) comprise a plurality of openings positioned within channels. The openings 318 associated with the vacuum ports are on the output face 303 of the gas distribution plate 30, rather than in a channel 317, but could also be positioned within a channel.

The specific embodiment shown in FIG. 4 has a combination of elongate gas ports that will provide a specific sequence of gas streams to a substrate surface when the substrate is moved perpendicularly to the elongate gas ports along arrow 350. Although the substrate is described as being moved, it will be understood by those skilled in the art that the substrate can remain stationary and the gas distribution plate 30 can move. It is the relative movement between the substrate and gas distribution plate 30 that is referred to as substrate movement. The substrate, moving perpendicularly to the elongate gas ports will be subjected to gas flows of, in order, a purge gas stream, a first precursor gas A stream, a purge gas stream, a second precursor gas B stream, a purge gas stream, a first precursor gas A′ stream and a purge gas stream. Between each of the gas streams are vacuum ports which direct the gas streams out of the processing chamber. This results in a flow pattern in accordance with arrow 198 shown in FIG. 1.

In specific embodiments, the gas distribution plate consists essentially of, in order, a leading first precursor gas port A, a second precursor gas port B and a trailing first precursor gas port A′. As used in this context, and in the appended claims, the term “consisting essentially of” means that the gas distribution plate does not include any additional gas ports for reactive gases. Ports for non-reactive gases (e.g, purge gases) and vacuum can be interspersed throughout while still being within the consisting essentially of clause. For example, the gas distribution plate 30 may have eight vacuum ports V and four purge ports P but still consist essentially of a leading first precursor gas port A, a second precursor gas port B and a trailing precursor gas port A′. Embodiments of this variety may be referred to as an ABA configuration.

The use of the ABA configuration ensures that a substrate moving from either direction will encounter a first precursor gas A port before encountering a second precursor gas B port. Each pass across the gas distribution plate 30 will result in a single film of composition B. Here, the two first precursor gas A ports surround the second precursor gas B port so that a substrate moving (relative to the gas distribution plate) from top-to-bottom of the figure will see, in order, the leading first reactive gas A, the second reactive gas B and the trailing first reactive gas A′, resulting in a full layer being formed on the substrate. A substrate returning along the same path will see the opposite order of reactive gases, resulting in two layers for each full cycle. A substrate moved back and forth across this gas distribution plate will be exposed to a pulse sequence of

AB AAB AAB (AAB)ₙ . . . AABA

forming a uniform film composition of B. Exposure to the first precursor gas A at the end of the sequence is not important as there is no follow-up by a second precursor gas B. It will be understood by those skilled in the art that while the film composition is referred to as B, it is really a product of the surface reaction products of reactive gas A and reactive gas B and that use of just B is for convenience in describing the films.

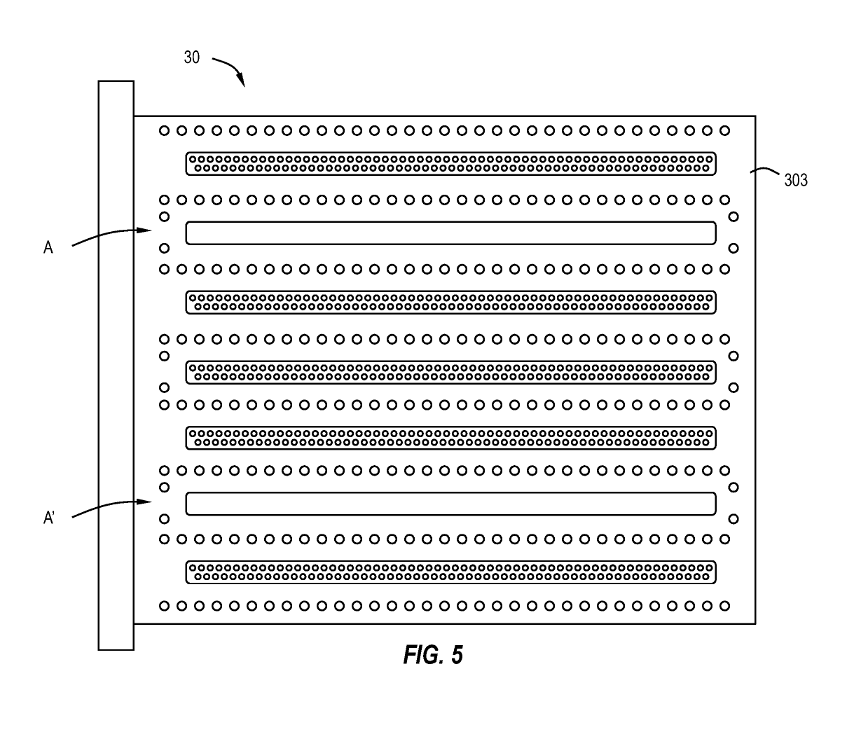

FIG. 5 shows another detailed embodiment of the gas distribution plate 30 in which the channels for the leading first precursor gas port A and the trailing first precursor gas port A′ are fully open, as opposed to that of FIG. 4 in which there are a plurality of openings 315 within the channel 317. Again, this embodiment is shown in an ABA configuration but could just as easily include multiple sets of AB gas injectors spanning any desired number. For example, the gas distribution plate may have 100 sets of AB gas injectors, each individually controlled, and each individually containing a hot wire, tensioner and power source.

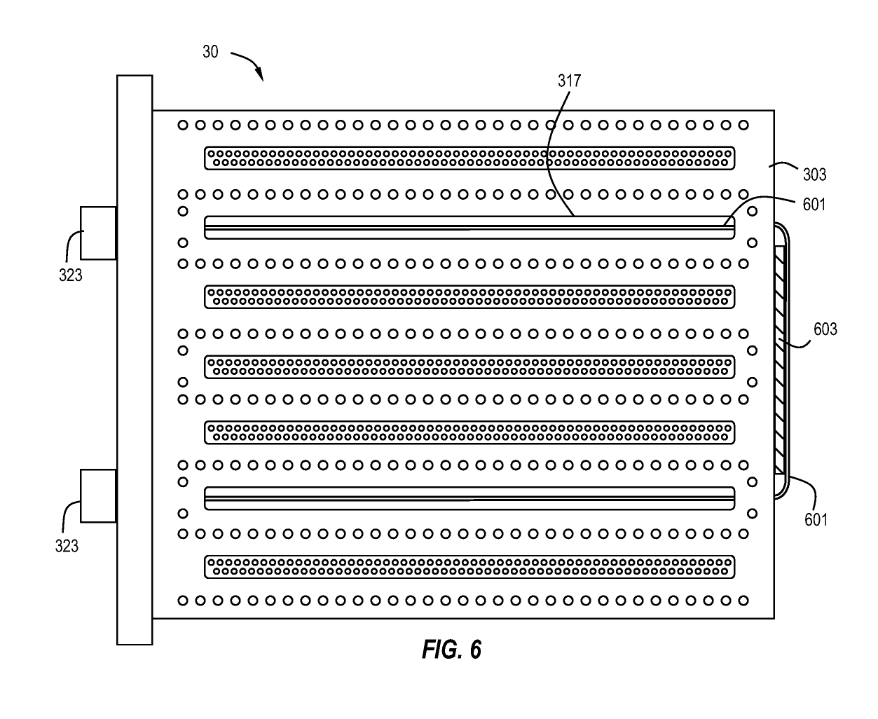

The gas distribution plate 30, as shown in FIG. 6, includes a wire 601, which may be referred to as a hot wire, to excite gaseous species. The wire 601 is positioned in either or both of the first precursor gas port and the second precursor gas port. The wire is connected to a power lead 323 (shown in FIG. 3) configured to cause a flow of current through the wire 601 to heat the wire 601. The wire 601 is heated to high temperatures to excite the species in the gas passing adjacent the wire 601. A purpose of the wire is to create the radical species in the gas, not to create a temperature increase in the substrate. The wire can be placed in a position in which there is no direct exposure to the surface of the substrate, while still be able to cause radical species formation in the gas. For example, if the wire 601 is placed in the second precursor gas ports, then the wire will cause a portion of the molecules in the second precursor gas to become excited. In the excited state the molecules have higher energy and are more likely to react with the substrate surface at a given processing temperature.

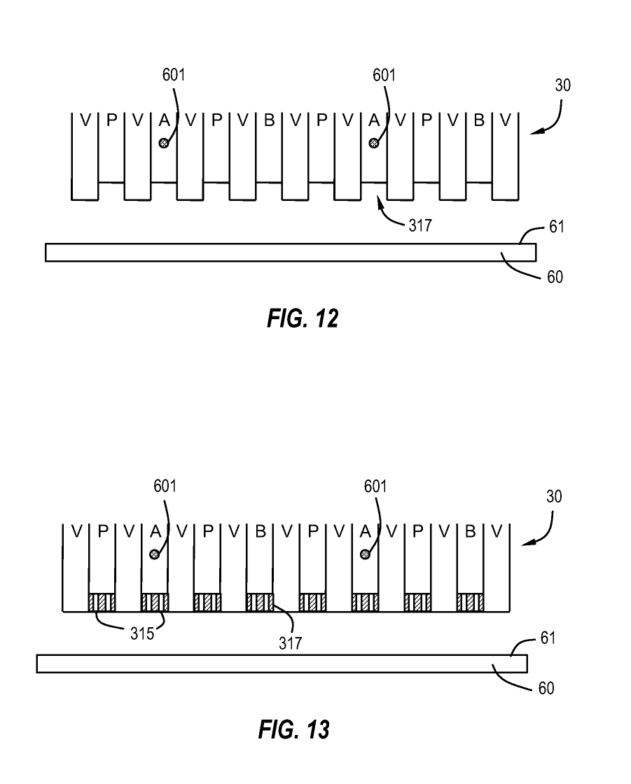

The placement of the wire may have an impact on the degree of radical species contacting the substrate. Placing the wire too far from the substrate may allow a larger number of radical species, than a closer placement, to become deactivated before contacting the substrate surface. The radical species may become deactivated by contact with other radicals, molecules in the gas stream and the gas distribution plate. However, placing the wire further from the substrate may help prevent the wire from heating the substrate surface while still creating radical species in the gas. The wire 601 may be placed close enough to the surface of the substrate to ensure that excited species exist long enough to contact the surface without causing significant change in local temperature of the substrate. As used in this specification and the appended claims, the term “significant change in local temperature” means that the portion of the substrate adjacent the wire does not have an increase in temperature greater than about 10° C. FIG. 12. Shows a side view of an embodiment of the invention in which the wire 601 is positioned within channel 317. This embodiment does not have a gas diffusing component (e.g., a showerhead or plurality of holes). With nothing to obstruct In some embodiments, the heated wire 601 may causes a change in temperature of a portion of the substrate adjacent the channel containing the wire 601. FIG. 13 shows another embodiment of the invention in which the wire 601 is positioned within a channel 317 having a gas diffusing component with a plurality of openings 315. The heated wire 601 positioned behind the gas diffusing component may be capable of exciting the gaseous species without significantly changing the local temperature of the substrate. In detailed embodiments, the wire is heated to excite gaseous species while causing a surface temperature change of less than about 10° C. In various embodiments, the local change in temperature of the substrate surface is less than about 7° C., 5° C. or 3° C. In specific embodiments, the local temperature change is less than about 2° C., 1° C. or 0.5° C.

The wire can be made of any suitable material capable of being elevated to high temperature in a relatively short period of time. A suitable material is one which is compatible with the reactive gases. As used in this specification and the appended claims, the term “compatible” used in this regard means that the wire is not spontaneously reactive with the reactive gas at standard temperature and pressure. The temperature of the wire may have an impact on the degree of radicalization of the gaseous species. For example, oxygen may require temperature up to about 2000° C., while polymeric species may only need temperatures in the range of about 300° C. to about 500° C. In some embodiments, the wire is capable of being heated to a temperature of at least about 1000° C., 1100° C., 1200° C., 1300° C., 1400° C., 1500° C., 1600° C., 1700° C., 1800° C., 1900° C. or 2000° C. In various embodiments, the wire is capable of being heated to a temperature in the range of about 300° C. to about 2000° C., or in the range of about 700° C. and about 1400° C., or in the range of about 800° C. to about 1300° C. Power supplied to the wire can be modulated or turned on and off at any point throughout the processing. This allows the wire to be heated, creating excited gaseous species, for only a portion of the processing.

The thickness and length of the wire can also be changed depending on the material used. Examples of suitable materials for the wire include, but are not limited to, tungsten, tantalum, iridium, ruthenium, nickel, chromium, graphite and alloys thereof. For example, where oxygen is the species being radicalized, the use of tantalum or tungsten may not be desired as these materials are sensitive to oxygen and may cause breakage of the wire. In detailed embodiments, the wire comprises tungsten.

The wire can have any suitable density per unit length depending on the material used in the wire. In some embodiments, the wire has a substantially uniform density per unit length. As used in this specification and the appended claims, the term “substantially uniform” means that the density per unit length of the wire does not change by more than 20%, 15%, 10%, 5%, 3%, or 1% over the entire length of the wire. However, it may be advantageous to vary the density per unit length of the wire across the length of the wire. For example, upon heating the wire may tend to sag more in the middle of the length than at the end of the length. Here, a wire with a lower density per unit length in the middle of the wire may provide a more consistent process. However, in some embodiments, it may be more beneficial to have the middle of the wire length be of higher density per unit length.

The shape of the wire can also be varied depending on factors such as, but not limited to, the degree of ionization desired and the material that the wire is made of. In some embodiments the wire is substantially straight or substantially linear. As used in this specification and the appended claims, the terms “substantially straight” and “substantially linear” mean that there is less than a 10%, 5%, 3% or 1% deviation in linearity of the wire over the entire length.

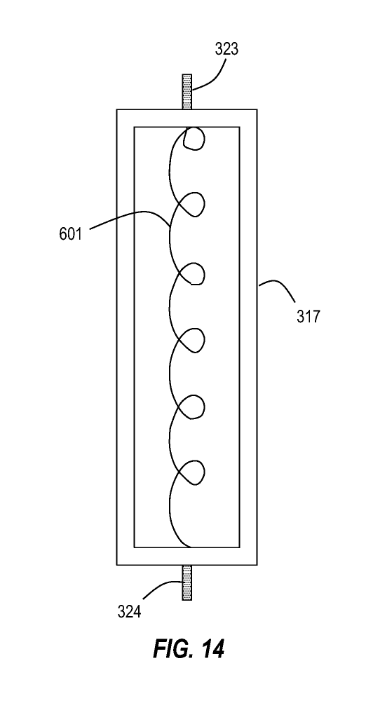

In some embodiments, the wire has a nonlinear shape. For example, the liar can be folded, accordion shaped, looped or helical. We nonlinear wire is used, the tension provided on the ends of the wire may cause the wire shape to change slightly as the wire is heated up. Changing the shape of the wire may also provide a larger surface area upon which ionization can occur. FIG. 14 shows a helical shaped wire in accordance with one or more embodiments of the invention.

Referring back to FIG. 3, the power source can be any suitable power source capable of controlling current flow through the wire. The power feedthrough 321 shown in FIG. 3 has a power lead 323 and a tensioner 325. The power feedthrough 321 provides both mechanical and electrical support for the wire and allows the wire to be placed in the path of the gas flow. The power feedthrough 321 is connected to the gas distribution plate 30 through a mounting block 327 which may include an insulator to electrically isolate the power lead 323 and the wire from the gas distribution plate. The wire in the embodiment of FIG. 3 extends through the first precursor gas channels and can be individual wires or a single wire which wraps around the second precursor gas channel.

FIG. 6 shows a detailed embodiment of the invention in which the gas distribution plate is in an ABA configuration and the wire 601 is a single wire extending along both first precursor gas ports (A and A′) and wrapping around the second precursor gas port B. An insulating material 603 may be present at the end of the gas distribution plate 30 so that the wire 601 does not contact the gas distribution plate 30. Additionally, the portions of the wire 601 not exposed in the gas channels can be insulated. For ease of presentation, the wire 601 has been illustrated in an open channel 317, meaning a channel without a plurality of openings (as shown in FIG. 4). However, the wire 601 could also be placed within the channel 317 behind the plurality of openings.

In embodiments of the sort shown in FIG. 6, the power leads 323 (see FIG. 3) at the input face 301 must be of opposite polarity to allow current flow. Therefore, one power lead 323 will be positive and other negative. This configuration may be relatively easy to setup, with a single power source being connected to both of the power leads 323. The single power source (not shown) may include a mechanism to control the current flowing through the wire, such as a potentiometer.

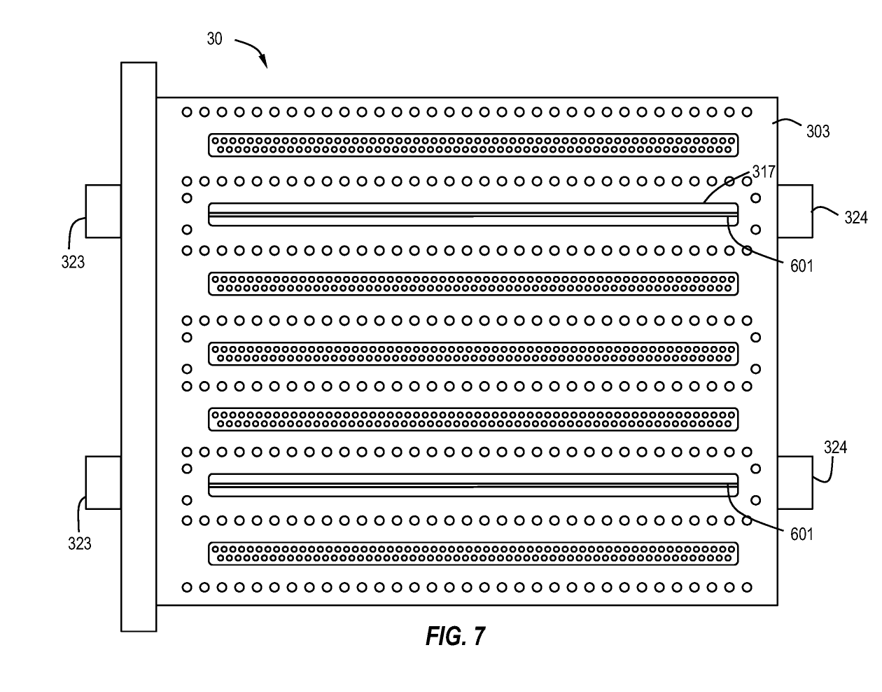

In an alternate detailed embodiment, shown in FIG. 7, the gas distribution plate is made up of an ABA configuration and there are two wires. Each of the two wires extend along one of the leading first precursor port A and the trailing first precursor gas port A′. Accordingly, each of the wires needs to have a separate power source for supplying a flow of current across the wire. Additionally, each wire will need a second power lead 324 for connection with the power supply to complete the circuit. In some embodiments, the wire extends along the second precursor gas port to excited species in the second precursor gas.

The wire of some embodiments can be part of a discrete hot wire unit. The hot wire unit can be inserted into the gas distribution plate 30 through one of the gas inlets in the input face. In these embodiments, the wire, associated clamps, power leads and tensioner are combined as a single unit. The unit can have a tubular or rectangular cross-section and is sized to fit into the gas passageways within the gas distribution plate. The hot wire unit includes an alternate gas inlet (as seen in FIG. 3), and openings to exhaust the gas flow. This allows the gas to flow through the hot wire unit, contacting the wire and being exhausted from the output face of the gas distribution plate.

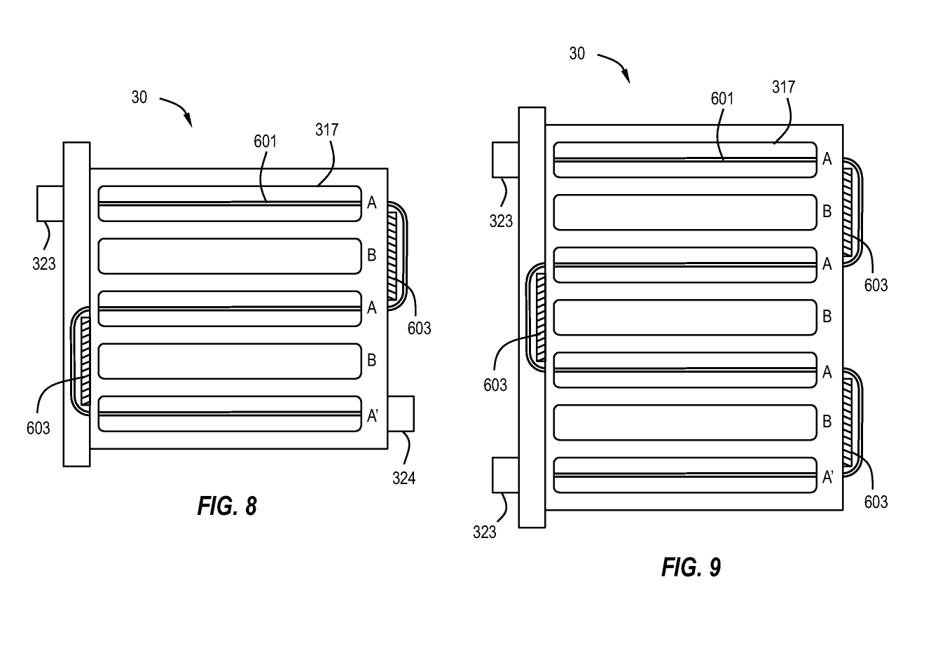

In some embodiments, the gas distribution plate 30 comprises a plurality if elongate gas ports consisting essentially of, in order, at least two repeating units of alternating first precursor gas A ports and second precursor gas B ports followed by a trailing first precursor gas A′ port. Stated differently, a combination of a first precursor gas A port and a second precursor gas B port, which may be referred to as an AB unit, is repeated at least two times, with a trailing first precursor gas A′ port. FIGS. 8 and 9 illustrate embodiments of these sorts. The gas distribution plates 30 shown in FIGS. 8 and 9 only show channels 317 associated with the first precursor gas A and the second precursor gas B. The purge gases and vacuum ports have been omitted for illustrative purposes only. Additionally, each of the channels 317 is illustrated as open channels without a plurality of openings as seen in FIG. 4. Those skilled in the art will understand that the purge, vacuum and plurality of openings may be present in the gas distribution plate 30.

FIG. 8 has two repeating AB units with a trailing first precursor gas port A′, resulting in an ABABA configuration. Accordingly, each full cycle (one back and forth movement of a substrate through the gas streams) will result in deposition of four layers of B. FIG. 9 is similar to that of FIG. 8 with the addition of a third AB unit. This makes a gas distribution plate with an ABABABA configuration. Accordingly, each full cycle will result in the deposition of six layers of B. Including a trailing first precursor gas port A′ in each of these configurations ensures that a substrate moving relative to the gas distribution plate will encounter a first precursor gas port before a second precursor gas port regardless of which side of the gas distribution plate 30 the movement originates. Although the embodiments shown include two or three repeating AB units, it will be understood by those skilled in the art that there can be any number of repeating AB units in a given gas distribution plate 30. The number of repeating AB units can vary depending on the size of the gas distribution plate. In some embodiments, there are in the range of about 2 and about 128 AB units. In various embodiments, there are at least about 2, 3, 4, 5, 10, 15, 20, 25, 30, 35, 40, 45 or 50 AB units. Additionally, it will be understood by those skilled in the art that this configuration is merely illustrative and that the gas distribution plate can comprise any number of gas injectors. For example, a gas distribution plate may have 100 repeating AB units, with or without a trailing first gas port A′.

In some embodiments, as shown in FIGS. 8 and 9, the wire 601 extends along each of the first precursor gas ports. The wire can be a single wire which winds through the various first precursor gas ports. In FIG. 8, because there are an odd number of first precursor gas ports, a second power lead 324 is positioned at the end of the trailing first precursor gas A′ port. In FIG. 9, as there are an even number of first precursor gas ports, both terminals of the power leads 323 are positioned on the same side of the gas distribution plate 30. Although the wire is shown in the first precursor gas ports, it will be understood that the wire can extend along each of the second precursor gas ports, instead of, or in addition to a wire in the first precursor gas ports. Additionally, individual wires can be employed for each of the precursor gas ports, similar to FIG. 7. When individual wires are used, there must be separate positive and negative power leads for each wire.

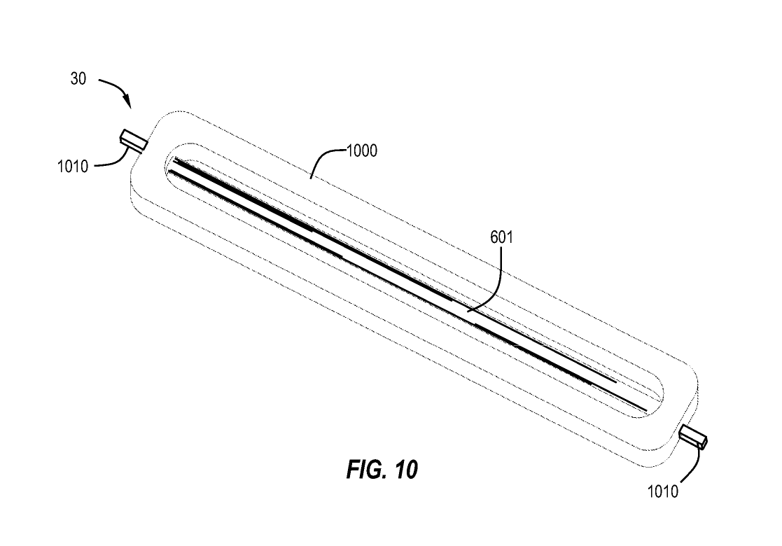

FIG. 10 shows another embodiment of the invention in which the wire 601 is mounted within an enclosure 1000. The enclosure 1000 can be sized to fit within the channels 317 of the gas distribution plate 30 so that the wire can 601 can be easily added or removed from the gas distribution plate 30. The enclosure 1000 can be attached to the output face of the gas distribution plate 30 and positioned so that the gases exiting the precursor gas port passes through the enclosure 1000. The enclosure may also include electrical leads 1010 in electrical communication with the wire 601 to allow current flow through the wire 601. The electrical leads 1010 can interact with electrical contacts positioned on the gas distribution plate. For example, pairs of electrical contacts (positive and negative contacts) can be included in the channels of the gas distribution plate. Each of these electrical contact pairs can be powered individually or as one or more units. When an enclosure 1000 is inserted into the channel 317 of the gas distribution plate, the electrical leads 1010 on the enclosure form an electrical connection with the electrical contacts on the gas distribution plate so that current can flow through the wire 601. Incorporating the wire 601 into the enclosures 1000 allows the wire 601 to be easily removed from the processing chamber to be replaced or cleaned.

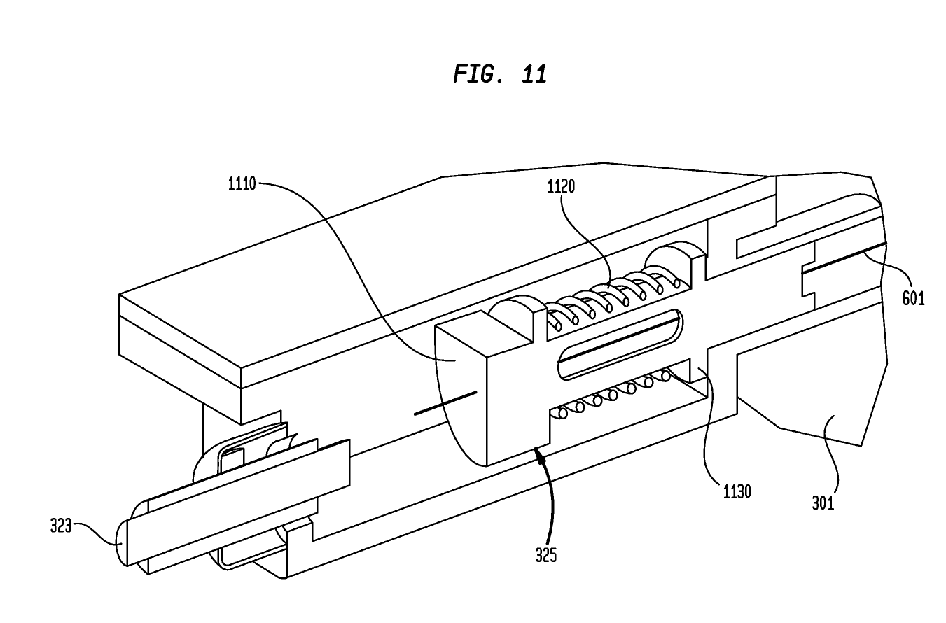

The wire 601 is maintained at a selected tension or in a range of tensions. Heating the wire will cause the wire to expand and sag. To compensate for this sag, a tensioner 325, shown in an isometric cross-sectional view in FIG. 11 can be included. The tensioner 325 is connected to the wire 601 to provide a tension on the wire 601. A clamp 1110 holds a first end of the wire 601 in connection with the power lead 323 (not shown touching). A bushing 1130 connects the tensioner 325 with the gas port and may provide a gas tight seal so that precursor gases flowing into the gas port are not able to flow into the tensioner body. A spring 1120 is positioned between the bushing 1130 and the clamp 1110 to provide the tension on the wire 601. Although a spring 1120 is shown and described, it should be understood that other tensioning mechanisms can be employed.

The tensioner 325 is capable of providing sufficient tension to prevent significant sagging in the wire. Additionally, the tensioner 325 is configured to provide less tension on the wire than would be required to cause breakage of the wire. As used in this specification and the appended claims, the term “significant sagging” means that there is a sag to length ratio of less than about 0.1, or less than about 0.05, or less than about 0.01, or less than about 0.005 or less than about 0.0025. In various embodiments, the sag is less than about 4 mm over a 400 mm length, or less than about 3 mm over a 400 mm length, or less than about 2 mm over a 400 mm length, or less than about 1 mm over a 400 mm length, or less than about 4 mm over a 300 mm length, or less than about 3 mm over a 300 mm length, or less than about 2 mm over a 300 mm length, or less than about 1 mm over a 300 mm length. Springs may be useful as tensioning mechanisms because the materials and spring constants can be tuned to match the requirements of the particular wire parameters (e.g., material, length, thickness).

Additional embodiments of the invention are directed to methods of processing a substrate. A substrate is laterally moved adjacent a gas distribution plate 30 as described herein. The substrate can be moved either beneath or above the gas distribution plate. A first precursor gas is delivered to the substrate surface from a first precursor gas port. A second precursor gas is delivered to the substrate surface from a second precursor gas port. A wire is positioned within one or more of the first precursor gas port and the second precursor gas port. Power is applied to the wire to cause the temperature of the wire to become elevated. The wire is elevated to a temperature high enough to cause excitation of gaseous species passing the wire. The excited species react with the substrate surface.

Another embodiment of the invention is directed to a method of processing a substrate. The substrate is moved laterally adjacent a gas distribution plate. The gas distribution plate has a plurality of elongate gas ports consisting essentially of, in order, a leading first precursor gas port, a second precursor gas port and a trailing first precursor gas port. The surface of the substrate is sequentially contacted with, in order, a first precursor gas stream from the leading first precursor gas port, a second precursor gas stream from the second precursor gas port and a first precursor gas stream from the trailing first precursor gas port. Gaseous species, from either or both of the first precursor gas and the second precursor gas is excited by exposing the gas to high temperature wire within the path of the gas stream before the gas contacts the surface of the substrate.

Embodiments of the invention can be incorporated into systems with a single gas distribution plate were met gas distribution plates. For example, one or more embodiments are used in a carousel type processing system in which one or more substrates are transported in a circular or oval path adjacent one or more gas distribution plates. This may be particularly useful for high throughput operations. Suitable apparatuses that can incorporate the gas distribution plates described can be any shape and are not limited to linear or round processing paths. Those skilled in the art will understand the matter in which these gas distribution plates can be employed.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A gas distribution plate, comprising:
an input face comprising a first precursor gas input configured to receive a flow of a first precursor gas and a second precursor gas input configured to receive a flow of a second precursor gas;
an output face having a plurality of elongate gas ports configured to direct flows of gases toward a substrate adjacent the output face, the elongate gas ports including at least one first precursor gas port and at least one second precursor gas port, the at least one first precursor gas port in flow communication with the first precursor gas and the at least one second precursor gas port in flow communication with the second precursor gas; and
a wire positioned within at least one of the first precursor gas port and the second precursor gas port, the wire connected to a power source to heat the wire.

2. The gas distribution plate of claim 1, further comprising a tensioner connected to the wire to provide a tension.

3. The gas distribution plate of claim 2, wherein the tensioner comprises a spring.

4. The gas distribution plate of claim 2, wherein the tension is sufficient to prevent significant sagging in the wire and breakage of the wire.

5. The gas distribution plate of claim 2, wherein the tensioner is attached to the input face.

6. The gas distribution plate of claim 1, wherein the wire comprises tungsten.

7. The gas distribution plate of claim 1, wherein the wire is within an enclosure attached to the output face and positioned so that gases exiting one or more of the first precursor gas port and the second precursor gas port pas through the enclosure.

8. The gas distribution plate of claim 1, wherein the plurality of elongate gas ports consist essentially of, in order, a leading first precursor gas port, a second precursor gas port and a trailing first precursor gas port.

9. The gas distribution plate of claim 8, wherein the wire is a single wire extending along both first precursor gas ports and wrapping around the second precursor gas port.

10. The gas distribution plate of claim 8, wherein there are two wires, a first wire extending along the leading first precursor gas port and a second wire extending along the trailing first precursor gas port.

11. The gas distribution plate of claim 1, wherein the wire extends along the at least one second precursor gas port.

12. The gas distribution plate of claim 1, wherein the plurality of elongate gas ports consist essentially of, in order, at least two repeating units of alternating first precursor gas ports and second precursor gas ports followed by a trailing first precursor gas port.

13. The gas distribution plate of claim 12, wherein the wire extends along each of the first precursor gas ports.

14. The gas distribution plate of claim 12, wherein the wire extends along each of the second precursor gas ports.

15. The gas distribution plate of claim 1, wherein the wire can be heated to excite species in a gas flowing across the wire.

16. A deposition system, comprising a processing chamber with the gas distribution plate of claim 1.

17. A method of processing a substrate comprising:
laterally moving a substrate having a surface beneath a gas distribution plate comprising a plurality of elongate gas ports including at least one first precursor gas port to deliver a first precursor gas and at least one second precursor gas port to deliver a second precursor gas;
delivering the first precursor gas to the substrate surface;
delivering the second precursor gas to the substrate surface; and
applying power to a wire positioned within one or more of the at least one first precursor gas port and the at least one second precursor gas port to excite gaseous species in one or more of the first precursor gas and the second precursor gas, the excited species reacting with the surface of the substrate.

18. The method of claim 17, further comprising applying a tension to the wire, the tension sufficient to prevent significant sagging of the wire and breakage of the wire.

19. A method of processing a substrate, comprising:
laterally moving the substrate adjacent a gas distribution plate having a plurality of elongate gas ports, the plurality of elongate gas ports consisting essentially of, in order, a leading first precursor gas port, a second precursor gas port and a trailing first precursor gas port;
sequentially contacting a surface of the substrate to, in order, a first precursor gas stream from the leading first precursor gas port, a second precursor gas stream from the second precursor gas port and a first precursor gas stream from the trailing first precursor gas port; and
exciting a gaseous species in one or more of the first precursor gas and the second precursor gas before contacting the surface of the substrate by powering a wire positioned within either both the leading and trailing first precursor gas port or the second precursor gas port.

20. The method of claim 19, further comprising adjusting tension of the wire to prevent substantial sagging and breakage of the wire.
